(19) United States
(12) Patent Application Publication
(10) Pub. No.: US 2009/0032861 A1
(43) Pub. Date: Feb. 5, 2009

(54) NONVOLATILE MEMORIES WITH CHARGE TRAPPING LAYERS CONTAINING SILICON NITRIDE WITH GERMANIUM OR PHOSPHORUS

(76) Inventors: Zhong Dong, Fremont, CA (US); Chiliang Chen, Sunnyvaley, CA (US); Ching-Hwa Chen, Milpitas, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/830,524

(22) Filed: Jul. 30, 2007

(51) Int. Cl. H01L 29/792; H01L 21/3205

(52) U.S. Cl. 257/324; 438/591; 257/E29.309; 257/E21.294

(57) ABSTRACT

A nonvolatile memory has a charge trapping layer which includes a layer (130) made of silicon nitride doped with germanium or phosphorus (210). The germanium or phosphorus contains a large percentage of scattered, non-crystallized atoms uniformly distributed in the silicon nitride layer to increase the charge trapping density.

### BACKGROUND OF THE INVENTION

The present invention relates to nonvolatile memories, and more particularly to memories with charge trapping regions containing silicon nitride.

FIG. 1A shows a vertical cross section of a nonvolatile memory cell. The cell's channel region 110 is formed in a P type monocrystalline silicon substrate 122. N type source and drain regions 124 are formed in substrate 122 at the opposite ends of the channel region. Charge trapping region 130 overlies the channel region. Conductive control gate 140, e.g. doped polysilicon or tantalum, overlies the charge trapping region.

Tunnel dielectric 150 is formed between charge trapping region 130 and substrate 122 to reduce charge leakage from the charge trapping region to the substrate. Blocking dielectric 170 is formed between charge trapping region 130 and gate 140 to reduce charge leakage from the charge trapping region to the gate. Charge trapping region 130 can be formed of silicon nitride (Si₃N₄). Dielectric layer 150 can be silicon dioxide, and dielectric 170 can be silicon dioxide or aluminum oxide. See e.g. U.S. patent application published as no. 2006/0261401 A1 on Nov. 23, 2006, filed by A. Bhattacharyya on May 17, 2005, incorporated herein by reference.

When gate 140 is at a positive voltage relative to channel 110 or a source/drain region 124, some electrons in channel 110 or source/drain region 124 gain enough energy to tunnel through dielectric 150 into charge trapping region 130. The electrons become trapped in the charge trapping region, increasing the threshold voltage of the memory cell. The threshold voltage can be sensed by sensing the current between source/drain regions 124 when suitable voltages are applied to control gate 140, substrate 122, and source/drain regions 124. When a negative voltage is applied to gate 140 relative to channel 110 or a source/drain region or regions 124, the cell's threshold voltage returns to its original state.

Charge trapping region 130 can be provided with silicon, germanium, or metal nanocrystals 180. Each nanocrystal contains a few hundred atoms. The nanocrystals serve as additional trapping sites for electron trapping. Higher trapping site density is therefore achieved to provide a more reliable threshold voltage differentiation and to counteract leakage of trapped charges from the charge trapping layer.

Germanium enhancement of silicon nitride is also described in an article by Chun-Hao Tu et al. entitled “Formation of silicon germanium nitride layer with distributed charge storage elements, published in Applied Physics Letters, vol. 88, issue 11, March 2006. See FIG. 1B. The article does not refer to nanocrystals, but rather describes “nitride-incorporated silicon germanium (SiGeN)” deposited at 200° C., 0.6 mTorr, and plasma power of 20 W from “SiH₄ (20 sccm), GeH₄ (5 sccm), NH₃ (30 sccm), and N₂ (500 sccm)”. The same temperature and pressure are then used to deposit a-Si, which is subsequently oxidized at 900° C. to form blocking oxide. The resulting charge trapping layer includes “Si—H, Ge—H, N—H, Si—N, and Ge—N bonds”. There are “dangling bonds or defects exist in the bulk and at the interface between SiGeN” and the blocking oxide.

Alternative techniques for increasing the charge trapping density are desirable.

### SUMMARY

This section summarizes some features of the invention. Other features are described in the subsequent sections. The invention is defined by the appended claims, which are incorporated into this section by reference.

Providing uniform, dense, reproducible distribution of nanocrystals 180 (FIG. 1A) in the charge trapping layer may involve complicated techniques and/or undesirably high temperatures. On the other hand, the Ge—H bonds in FIG. 1B are unstable, and the memory electrical characteristics may change during memory operation if these bonds become destroyed. Also, it is desirable to use low germanium concentrations because high concentrations change the energy band structure of the memory. The germanium concentration described above in connection with FIG. 1B seems to be 5:20=25% (atomic) relative to the silicon concentration based on the flow rates of 5 sccm for GeH₄ and 20 sccm for SiH₄.

Some embodiments of the present invention increase the charge trapping density by doping silicon nitride with germanium and/or phosphorus without requiring nanocrystal formation. In the germanium case, the germanium concentration can be less than 10% (atomic) relative to silicon. Alternatively, or in addition, chlorine can be used to form Ge—Cl bonds in the charge trapping layer. These bonds are typically more stable than Ge—H bonds (perhaps because chlorine atoms are heavier than hydrogen).

The invention is not limited to the features or advantages described above. Other features are described below. The invention is defined by the appended claims.

### BRIEF DESCRIPTION OF THE DRAWINGS

FIGS. 1A, 1B show vertical cross sections of charge trapping memory cells according to prior art.

FIGS. 2, 3 show vertical cross sections of charge trapping memory cells according to some embodiments of the present invention.

### DESCRIPTION OF SOME EMBODIMENTS

The embodiments described in this section illustrate but do not limit the invention. The invention is defined by the appended claims.

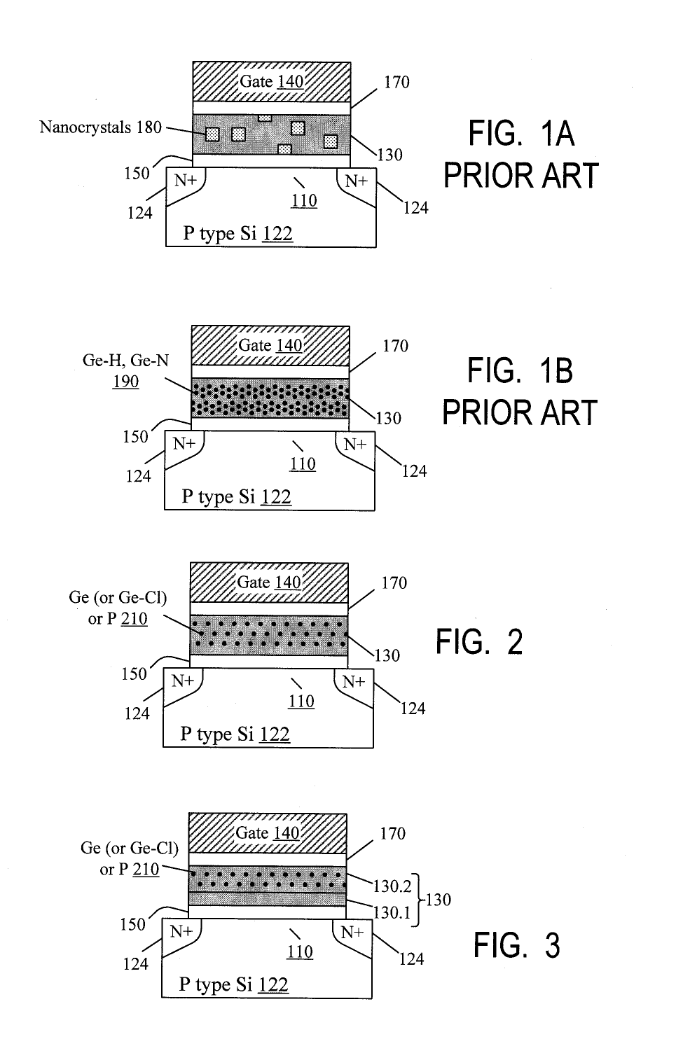

FIG. 2 shows a vertical cross section of a nonvolatile memory cell according to some embodiments of the present invention. P type channel region 110 and N+ type source/drain regions 124 at the ends of the channel region are formed in P type monocrystalline silicon substrate 122 as in FIGS. 1A, 1B, or in a P type well formed in the substrate and isolated from the rest of the substrate by pn junctions and/or dielectric regions (not shown). Tunnel dielectric 150, e.g. silicon dioxide or some other material, is formed on the channel region, possibly overlapping or covering the source/drain regions 124. Charge trapping layer 130 is formed on tunnel dielectric 150. Blocking dielectric 170, e.g. silicon dioxide, aluminum oxide, or some other material, is formed on charge trapping layer 130. Control gate 140 (e.g. doped polysilicon, metal (e.g. tantalum), or some other conductive material) is formed on blocking dielectric 170.

Charge trapping layer 130 is formed of silicon nitride SiₓN_{y} doped with germanium or phosphorus atoms 210. At least 95% percent of these atoms do not form crystals with each other, and in fact may have no bonds with each other. Germanium or phosphorus atoms may bind with silicon or nitrogen. We will call this material SiₓD_{z}N_{y} where D is germanium (Ge) or phosphorus (P). In some embodiments, the ratio (x+z):y is greater than 3:4. In some embodiments, the D atoms that do not form crystals with each other are uniformly distributed through the charge trapping layer 130.

In some germanium embodiments, the germanium concentration is under 10% (atomic) relative to the silicon concentration. This concentration can be achieved by reducing the flow rate of the germanium precursor (which can be GeH₄). In some phosphorus embodiments, the phosphorus concentration is under 10% (atomic) relative to the silicon concentration.

In some germanium embodiments, the germanium concentration may be under 10% or may be 10% or higher, but chlorine is also present in the charge trapping layer 130. The charge trapping layer thus may have Ge—Cl bonds.

The memory cell can be operated using prior art techniques, but the invention is not limited to such techniques. Suitable operation includes the techniques described above in connection with FIGS. 1A, 1B. Thus in some embodiments, to program the memory, gate 140 is driven to a positive voltage with respect to substrate 122 or source/drain region or regions 124. Electrons in channel 110 and/or one or both of source/drain regions 124 tunnel through dielectric 150 to charge trapping region 140. Either direct or Fowler-Nordheim tunneling can be used. Alternatively, channel hot electron injection (CHEI) can be used. In CHEI, a voltage difference is created between the source/drain regions 124. Gate 140 is driven to a positive voltage relative to channel 110 to invert the channel region to type N. Current flows between the source/drain regions through the channel, to provide hot electrons which pass through the dielectric 150 to reach the charge storage region. These electrons become trapped at the trapping sites in the charge storage region. The memory cell can be erased by driving the gate 140 to a negative voltage relative to channel 110 and/or one or both of source/drain regions 124. To read the memory, a voltage difference is created between the source/drain regions 124. Gate 140 is driven to a positive voltage relative to channel 110, so that the channel region becomes inverted if the memory is erased but not inverted (or the inversion is weaker) if the memory is programmed. Other programming/erasing/reading techniques, known or to be invented, may also be suitable.

In some embodiments, the memory is fabricated as follows. Dielectric 150 is formed on monocrystalline silicon substrate 122 using conventional techniques (e.g. thermal oxidation if dielectric 150 is silicon dioxide). Charge trapping layer 130 is formed on dielectric 150, for example, as follows. Silicon nitride is deposited by LPCVD (low pressure chemical vapor deposition) from ammonia (NH₃) and either tetrachlorosilane (TCS, SiCl₄) or dichlorosilane (DCS, SiH₂Cl₂). See e.g. U.S. Pat. No. 6,906,390 B2 issued Jun. 14, 2005 to Nomoto et al. and incorporated herein by reference. The TCS or DCS flow rate and the ammonia flow rate can be adjusted to provide the desired ratio x:y in the resulting SiₓN_{y} compound. In some embodiments, x=3 and y=4. In other embodiments, silicon-rich silicon nitride is formed (x:y>3:4) to increase the number of silicon dangling bonds. Additional silicon dangling bonds may provide additional charge trapping sites. The silicon nitride layer may contain chlorine residue, and additional chlorine containing reagents can be provided to increase chlorine concentration in the charge trapping layer. An exemplary chlorine concentration range is 0.1˜5% (atomic) relative to silicon, and other concentrations are possible. Chlorine is optional however.

Silicon nitride 130 is doped with germanium or phosphorus during or after deposition. In some embodiments, the doping is performed after the deposition as follows. A few monolayers of germanium are deposited by atomic layer deposition (from GeH₄ for example, or from a liquid source), or by epitaxial deposition (to reduce the hydrogen content), and then driven in by rapid thermal anneal (RTA). An exemplary anneal temperature is 900° C. or higher, and the exemplary anneal time is 30 seconds. The anneal can be combined with forming blocking layer 170 if suitable temperatures are used for the blocking layer, e.g. if the blocking layer is silicon dioxide obtained by high temperature oxidation of a silicon layer. In some embodiments, however, the blocking layer is aluminum oxide deposited at 400° C., or some other material deposited at relatively low temperatures, so RTA is used as a separate step for the germanium or phosphorus drive in. If chlorine is present in layer 170, some of germanium may bond with chlorine during the anneal to form Ge—Cl bonds. Germanium can also be introduced by ion implantation followed by RTA.

Alternatively, phosphorus doping is performed using liquid POCl₃. Phosphorus can be deposited and then driven in by thermal anneal, or can be introduced by ion implantation. In some embodiments, the phosphorus concentration is under 10% (atomic) relative to silicon, but other concentrations are also possible.

In still other embodiments, the phosphorus or germanium doping is performed during the silicon nitride deposition. An exemplary technique is atomic layer deposition (ALD).

Dielectric layer 170 is deposited on charge trapping layer 130, possibly by known techniques (e.g. CVD of silicon dioxide, or CVD of polysilicon or amorphous silicon followed by oxidation of the silicon, or deposition of aluminum oxide, or by some other techniques).

Doped polysilicon, tantalum, or some other conductive material or materials are deposited on dielectric 170 to form the gate layer 140. Then the layers 150, 130, 210, 170, 140 are patterned as desired, possibly using a single mask. Then N+ dopant is implanted to form source/drain regions 124.

This fabrication process is not limiting. For example, any one or more of layers 150, 130, 210, 170, 140 can be patterned using a separate mask, and the layers other than 140 can be patterned before the layer 140 deposition. The P and N conductivity types can be reversed. The charge trapping region may include multiple layers, e.g. layers 130.1, 130.2 in FIG. 3. One or both of these layers may include silicon nitride doped with germanium and/or phosphorus. For example, layer 130.1 can be undoped silicon nitride, and layer 130.2 can be silicon nitride doped with non-crystalline germanium or phosphorus as discussed above, to provide high charge trapping density in layer 130.2 but a lower density in layer 130.1. This may be desirable to enable the use of thinner oxide 150. See the aforementioned U.S. Pat. No. 6,906,390. Also, the layer 150 does not have to be silicon dioxide, and may include a stack of different layers (e.g. ONO). See e.g. the aforementioned U.S. patent application published as no. 2006/0261401 A1. Layers 150 and/or 170 can be omitted. The invention is not limited to any particular cell geometry. For example, all or part of channel 110 can be vertical, and all or part of charge trapping layer 130 can be formed in a trench in substrate 122. The memory cell can be a multi-level cell, with the charge trapping region divided into sub-regions each of which may store one bit of information. The invention is not limited to particular materials except as defined by the claims. Other embodiments and variations are within the scope of the invention, as defined by the appended claims.

1. An integrated circuit comprising nonvolatile memory comprising:
a channel region in a semiconductor substrate;
a charge trapping region adjacent to the channel region, for trapping charges to control the channel region's voltage, the charge trapping region comprising a layer of silicon nitride doped with germanium and containing chlorine, or doped with germanium without chlorine with germanium concentration being under 10 atomic percent relative to silicon; and
a conductive control gate adjacent to the charge trapping region and insulated from the channel region, for controlling the channel region's voltage.

2. The integrated circuit of claim 1 wherein said layer of the charge trapping region comprises germanium bonded to chlorine.

3. The integrated circuit of claim 1 wherein the germanium concentration in said layer of the charge trapping region is less than 10 atomic percent relative to silicon.

4. The integrated circuit of claim 1 wherein at least 95% of the germanium is provided by germanium atoms not bonded to each other.

5. An integrated circuit comprising nonvolatile memory comprising:
a channel region in a semiconductor substrate;
a charge trapping region adjacent to the channel region, for trapping charges to control the channel region's voltage, the charge trapping region comprising a layer of silicon nitride doped with phosphorus; and
a conductive control gate adjacent to the charge trapping region and insulated from the channel region, for controlling the channel region's voltage.

6. The integrated circuit of claim 5 wherein phosphorus concentration in said layer of the charge trapping region is under 10 atomic percent relative to silicon.

7. A method for manufacturing an integrated circuit comprising a nonvolatile memory cell, the method comprising:
forming a charge trapping region adjacent to a channel region of a semiconductor substrate, the charge trapping region comprising a layer comprising silicon nitride doped with germanium and containing chlorine, or doped with germanium without chlorine with germanium concentration being under 10 atomic percent relative to silicon;
forming a conductive control gate adjacent to the charge trapping region and insulated from the channel region, for controlling the channel region's voltage.

8. The method of claim 7 wherein said layer of the charge trapping region comprises germanium bonded to chlorine.

9. The method of claim 7 wherein the germanium concentration in said layer of the charge trapping region is less than 10 atomic percent relative to silicon.

10. The method of claim 7 wherein at least 95% of the germanium is provided by germanium atoms not bonded to each other.

11. A method for manufacturing an integrated circuit comprising a nonvolatile memory cell, the method comprising:
forming a charge trapping region adjacent to a channel region of a semiconductor substrate, the charge trapping region comprising a layer of silicon nitride doped with phosphorus; and
forming a conductive control gate adjacent to the charge trapping region and insulated from the channel region, for controlling the channel region's voltage.

12. The method of claim 11 wherein phosphorus concentration in said layer of the charge trapping region is under 10 atomic percent relative to silicon.
